(19) United States
(12) Patent Application Publication
(10) Pub. No.: US 2020/0240400 A1
(43) Pub. Date: Jul. 30, 2020

(54) MICRO-ELECTROMECHANICAL SYSTEM PUMP MODULE

(71) Applicant: Microjet Technology Co., Ltd., Hsinchu (TW)

(72) Inventors: Hao-Jan Mou, Hsinchu (TW); Rong-Ho Yu, Hsinchu (TW); Cheng-Ming Chang, Hsinchu (TW); Hsien-Chung Tai, Hsinchu (TW); Wen-Hsiung Liao, Hsinchu (TW); Chi-Feng Huang, Hsinchu (TW); Yung-Lung Han, Hsinchu (TW); Chang-Yen Tsai, Hsinchu (TW)

(73) Assignee: Microjet Technology Co., Ltd., Hsinchu (TW)

(21) Appl. No.: 16/749,550

(22) Filed: Jan. 22, 2020

(30) Foreign Application Priority Data
Jan. 24, 2019 (TW) 108102798

(51) Int. Cl. F04B 17/03; B81B 7/00

(52) U.S. Cl. CPC F04B 17/03; B81B 2207/07; B81B 2201/036; B81B 7/008

(57) ABSTRACT

A MEMS pump module includes a MEMS chip, at least one signal electrode, a plurality of MEMS pumps and a plurality of switch units. The MEMS chip comprises a chip body. The signal electrode is disposed on the chip body. Each of the MEMS pumps comprises a first electrode and a second electrode. The second electrode is electrically connected to the signal electrode. The switch units are electrically connected to the first electrodes of the MEMS pumps. A modulation voltage is received by the at least one signal electrode and then is transmitted to the second electrodes of the MEMS pumps. The on-off actions of MEMS pumps are controlled by the plurality of switch units.

### FIELD OF THE INVENTION

The present disclosure relates to a micro-electromechanical system (MEMS) pump module, and more particularly to a MEMS pump module having at least one signal electrode to reduce the number of contacts of a microprocessor, and utilizing at least one switch unit to control at least one MEMS pump, thereby simplifying the contacts and the routing of the MEMS pumps.

### BACKGROUND OF THE INVENTION

With the rapid development of technology, the applications of fluid transportation devices are becoming more and more diversified. For example, fluid transportation devices are gradually popular in industrial applications, biomedical applications, medical care applications, heat dissipation applications, or even the wearable devices. It is obvious that the trends of designing fluid transportation devices are toward the miniature structure. As known, reducing the size of the conventional pump to the millimeter scale is difficult, so the current miniature fluid transportation device usually uses a piezoelectric pump structure to transport fluid as an alternative.

Furthermore, by utilizing the MEMS pump structure, a pump can be minimized to have a nanoscale size. However, one single MEMS pump in nanoscale dimensions is so small that it can merely transport a limited amount of fluid. Consequently, more than one MEMS pumps are collaboratively operated to achieve the function as a pump.

FIG. 1 schematically illustrates a conventional MEMS pump module. As shown in FIG. 1, the MEMS pump module includes a high-level microprocessor 1 to control MEMS pumps 2, respectively. However, the cost of the high-level microprocessor 1 is high. In addition, each MEMS pump 2 is electrically connected to two pins 11 of the high-level microprocessor 1 and then is controlled by the high-level microprocessor 1, respectively, so as to precisely control the MEMS pump 2. However, the number of the pins of the high-level microprocessor 1 is very large in such arrangement. As a result, the cost of the high-level microprocessor 1 is further increased, the cost of the MEMS pump module is difficult to be reduced, and the difficulty of wire bonding process is increased. Consequently, the MEMS pump module is difficult to be widely used owing to its high cost. Therefore, there is a need of providing a MEMS pump module for reducing the cost.

### SUMMARY OF THE INVENTION

An object of the present disclosure provides a MEMS pump module. The MEMS pump module has at least one signal electrode to transport the modulated voltage for actuating the MEMS pump, and utilizes switch unit to control the on-off action of the MEMS pump, so as to reduce the number of contacts of the microprocessor, reduce the contacts and routing of the MEMS pump and further simplify the structure of the MEMS pump module.

In accordance with an aspect of the present disclosure, a MEMS pump module is provided. The MEMS pump module includes a MEMS chip, at least one signal electrode, a plurality of MEMS pumps and a plurality of switch units. The MEMS chip comprises a chip body. The signal electrode is disposed on the chip body. Each of the MEMS pumps comprises a first electrode and a second electrode. The second electrode is electrically connected to the at least one signal electrode. The switch units are electrically connected to the first electrodes of the MEMS pumps. A modulation voltage is received by the at least one signal electrode and then is transmitted to the second electrodes of the MEMS pumps. The on-off actions of MEMS pumps are controlled by the plurality of switch units.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 schematically illustrates a conventional MEMS pump module;

FIG. 2 schematically illustrates a MEMS pump module according to a first embodiment of the present disclosure;

FIG. 3 schematically illustrates a MEMS chip of a MEMS pump module according to a second embodiment of the present disclosure;

FIG. 4 schematically illustrates a MEMS chip of a MEMS pump module according to a third embodiment of the present disclosure;

FIG. 5 schematically illustrates a MEMS chip of a MEMS pump module according to a fourth embodiment of the present disclosure;

FIG. 6 schematically illustrates a MEMS chip of a MEMS pump module according to a fifth embodiment of the present disclosure;

FIG. 7 schematically illustrates a MEMS chip of a MEMS pump module according to a sixth embodiment of the present disclosure;

FIG. 8 schematically illustrates a MEMS chip of a MEMS pump module according to a seventh embodiment of the present disclosure;

FIG. 9 schematically illustrates a MEMS chip of a MEMS pump module according to an eighth embodiment of the present disclosure;

FIG. 10A schematically illustrates the connection between the switch unit and the MEMS pump according to of the present disclosure; and

FIG. 10B schematically illustrates the connection between the switch unit and the MEMS pump according to another embodiment of the present disclosure.

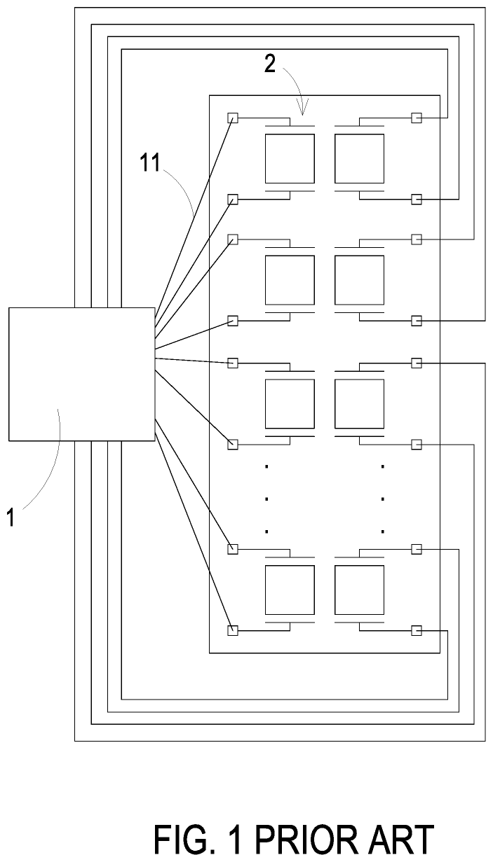

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

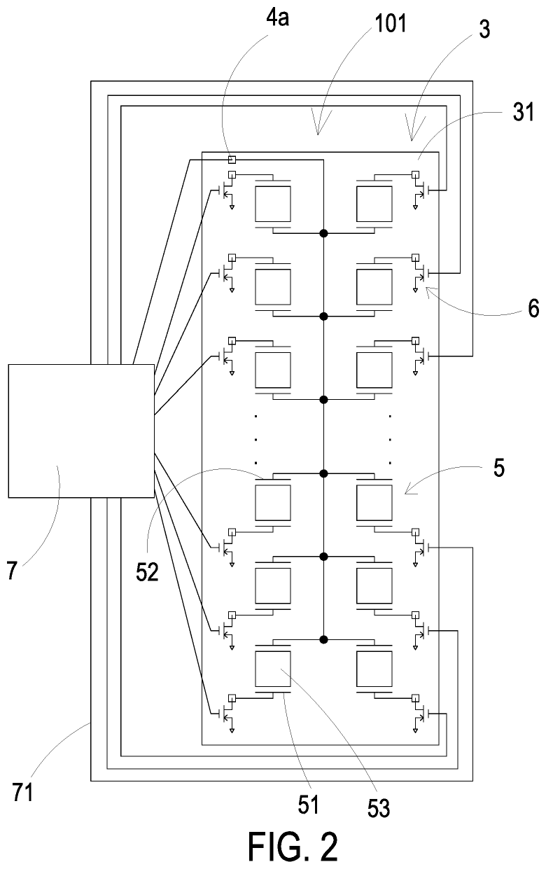

Please refer to FIG. 2. FIG. 2 schematically illustrates a MEMS pump module according to a first embodiment of the present disclosure. The MEMS pump module 101 includes a MEMS chip 3, at least one signal electrode 4, a plurality of MEMS pumps 5 and a plurality of switch units 6. The MEMS chip 3 includes a chip body 31. The signal electrode 4 is disposed on the chip body 31. The MEMS pumps 5 are disposed on the chip body 31. Each of the MEMS pumps 5 includes a first electrode 51, a second electrode 52 and a piezoelectric element 53. Each of the second electrodes 52 of the MEMS pumps 5 is electrically connected to the signal electrode 4. The piezoelectric element 53 of the MEMS pump 5 is deformed owing to piezoelectric effect, so that the inner pressure within the MEMS pump 5 is changed to inhale fluid and achieve the effect of transporting fluid. The switch units 6 are connected to the first electrodes 51 of the MEMS pumps 5. A modulation voltage from a microprocessor 7 is received by the signal electrode 4 and then is transmitted to the second electrodes 52 of the MEMS pumps 5. The modulation voltage is a square wave with the voltage value changed between ±1.8, ±3.3, ±3.6 or ±5. In addition, the modulation voltage can be an AC voltage performed in a sine wave or a triangle wave, but not limited thereto. A control signal from the microprocessor 7 is received by the switch unit 6, and the switch units 6 is turned on or off according to the control signal. Thereby, an on-off action of the MEMS pump 5 connected thereto is further controlled. More specifically, when the switch unit 6 is turned off, the circuit of the first electrode 51 of the MEMS pump 5 connected to the switch unit 6 is opened (i.e., interrupted), and the MEMS pumps 5 is stopped running; when the switch unit 6 is turned on, the first electrode 51 of the MEMS pump 5 connected to the switch unit 6 is considered to be grounded. Under this circumstance, the piezoelectric element 53 in the MEMS pump 5 is actuated by the modulation voltage received by the second electrode 52. Furthermore, in this embodiment, the signal electrode 4 includes a first signal electrode 4a. That is, the number of the signal electrode 4 is one. All of the second electrodes 52 of the MEMS pumps 5 are connected to the first signal electrode 4a, so that the modulation voltage is transmitted to the second electrodes 52 of the MEMS pumps 5 from the first signal electrode 4a.

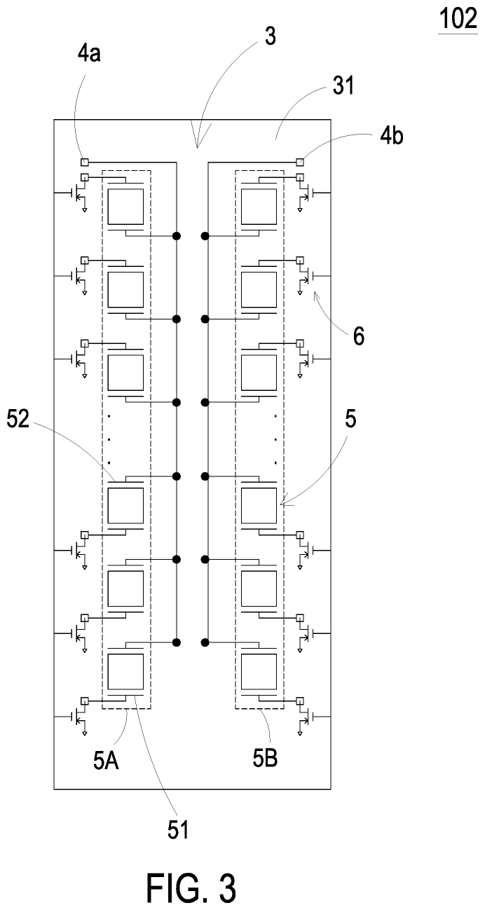

Please refer to FIG. 3. FIG. 3 schematically illustrates a MEMS chip of a MEMS pump module according to a second embodiment of the present disclosure. In this embodiment, the signal electrode 4 of the MEMS pump module 102 includes a first signal electrode 4a and a second signal electrode 4b. That is, the number of the signal electrode 4 is two. The plurality of MEMS pumps 5 are divided into a first MEMS pump group 5A and a second MEMS pump group 5B according to their positions on the MEMS chip 3. The second electrodes 52 of the MEMS pumps 5 in the first MEMS pump group 5A are electrically connected to the first signal electrode 4a. The second electrodes 52 of the MEMS pumps 5 in the second MEMS pump group 5B are electrically connected to the second signal electrode 4b. Consequently, an effect of partition control is achieved.

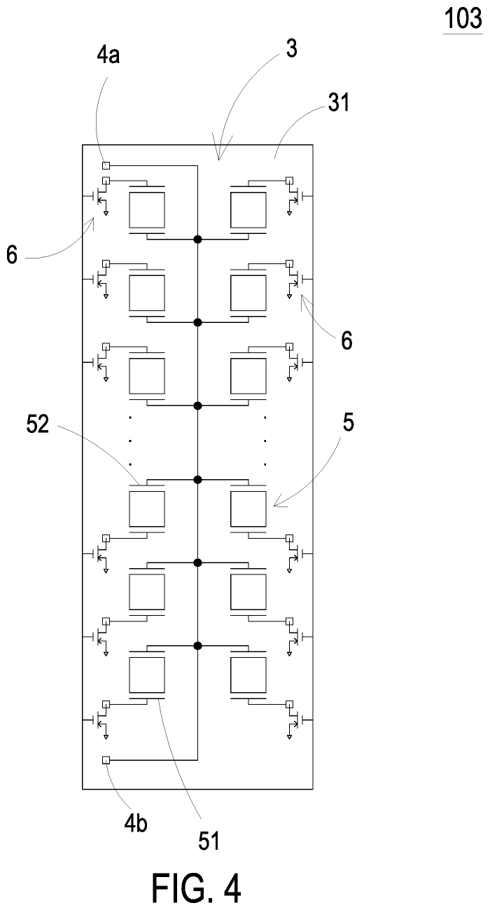

Please refer to FIG. 4. FIG. 4 schematically illustrates a MEMS chip of a MEMS pump module according to a third embodiment of the present disclosure. Like the second embodiment, the signal electrode 4 of the MEMS pump module 103 includes a first signal electrode 4a and a second signal electrode 4b. That is, the number of the signal electrode 4 is two. The first signal electrode 4a and the second signal electrode 4b are disposed on the chip body 31 and spatially separated from each other. More specifically, the first signal electrode 4a and the second signal electrode 4b are adjacent to the two opposite sides of the chip body 31, respectively. In addition, the first signal electrode 4a and the second signal electrode 4b are electrically connected to each other. The second electrodes 52 of the plurality of MEMS pumps 5 are electrically connected to both of the first signal electrode 4a and the second signal electrode 4b. Such design reduces the impedance between the second electrodes 52 of the plurality of MEMS pumps 5 and the signal electrodes 4. Consequently, the power loss of the modulation voltage transmitted to the second electrodes 52 at the positions away from the signal electrodes 4 is reduced.

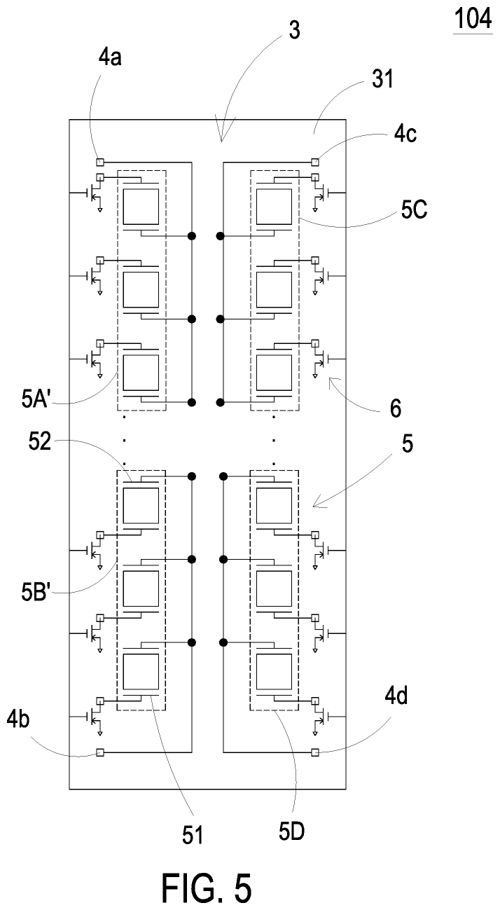

Please refer to FIG. 5. FIG. 5 schematically illustrates a MEMS chip of a MEMS pump module according to a fourth embodiment of the present disclosure. In this embodiment, the signal electrode 4 of the MEMS pump module 104 includes a first signal electrode 4a, a second signal electrode 4b, a third signal electrode 4c and a fourth signal electrode 4d. That is, the number of the signal electrode 4 is four. The first signal electrode 4a and the third signal electrode 4c are disposed adjacent to a first side of the chip body 31 and spatially separated from each other. The second signal electrode 4b and the fourth signal electrode 4d are disposed adjacent to a second side of the chip body 31 and spatially separated from each other. The first and second sides of the chip body 31 are opposite to each other. In this embodiment, according to the positions, the plurality of MEMS pumps 5 are divided into a first MEMS pump group 5A′, a second MEMS pump group 5B′, a third MEMS pump group 5C and a fourth MEMS pump group 5D. The MEMS pumps 5 disposed adjacent to the first signal electrode 4a belong to the first MEMS pump group 5A′ and all the second electrodes 52 of them are electrically connected to the first signal electrode 4a. The MEMS pumps 5 disposed adjacent to the second signal electrode 4b belong to the second MEMS pump group 5B′ and all the second electrodes 52 of them are electrically connected to the second signal electrode 4b. The MEMS pumps 5 disposed adjacent to the third signal electrode 4c belong to the third MEMS pump group 5C and all the second electrodes 52 of them are electrically connected to the third signal electrode 4c. The MEMS pumps 5 disposed adjacent to the fourth signal electrode 4d belong to the four MEMS pump group 5D and all the second electrodes 52 of them are electrically connected to the fourth signal electrode 4d. Consequently, an effect of partition control is achieved.

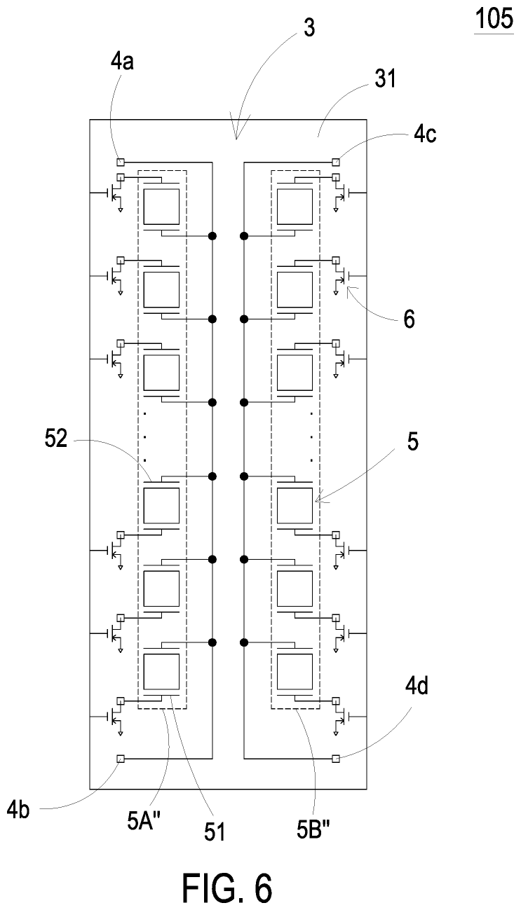

Please refer to FIG. 6. FIG. 6 schematically illustrates a MEMS chip of a MEMS pump module according to a fifth embodiment of the present disclosure. Like the fourth embodiment, the signal electrode 4 of the MEMS pump module 105 includes a first signal electrode 4a, a second signal electrode 4b, a third signal electrode 4c and a fourth signal electrode 4d. The locations of these signal electrodes 4a, 4b, 4c and 4d are identical to those of the fourth embodiment, while the electrical connecting relationships between these signal electrodes 4a, 4b, 4c and 4d are different. In this embodiment, the first signal electrode 4a and the second signal electrode 4b are electrically connected to each other, and the third signal electrode 4c and the fourth signal electrode 4d are electrically connected to each other. The plurality of MEMS pumps 5 are divided into a first MEMS pump group 5A″ and a second MEMS pump group 5B″. The MEMS pumps 5 disposed adjacent to the first signal electrode 4a or the second signal electrode 4b belong to the first MEMS pump group 5A″. The MEMS pumps 5 disposed adjacent to the third signal electrode 4c or the fourth signal electrode 4d belong to the second MEMS pump group 5B″. The second electrodes 52 of the plurality of MEMS pumps 5 in first MEMS pump group 5A″ are electrically connected to both of the first signal electrode 4a and the second signal electrode 4b. The second electrodes 52 of the plurality of MEMS pumps 5 in second MEMS pump group 5B″ are electrically connected to both of the third signal electrode 4c and the fourth signal electrode 4d. Consequently, an effect of partition control is achieved. Moreover, since the distances between the second electrodes 52 and the signal electrodes 4 are shortened, the power transmission loss of the modulation voltage is reduced.

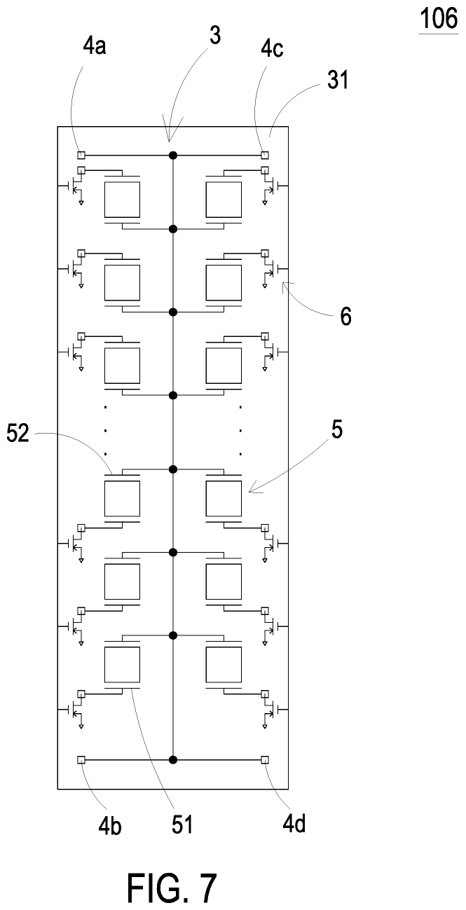

Please refer to FIG. 7. FIG. 7 schematically illustrates a MEMS chip of a MEMS pump module according to a sixth embodiment of the present disclosure. Like the fourth embodiment, the signal electrode 4 of the MEMS pump module 106 includes a first signal electrode 4a, a second signal electrode 4b, a third signal electrode 4c and a fourth signal electrode 4d. The locations of these signal electrodes 4a, 4b, 4c and 4d are identical to those of the fourth embodiment, while the electrical connecting relationships between these signal electrodes 4a, 4b, 4c and 4d are different. In this embodiment, the first signal electrode 4a, the second signal electrode 4b, the third signal electrode 4c and the fourth signal electrode 4d are all electrically connected with each other. Consequently, the second electrodes 52 of the plurality of MEMS pumps 5 are allowed to be electrically connected to the nearest one of the signal electrodes 4. For example, the second electrodes 52 of the MEMS pumps 5 near the first signal electrode 4a are electrically connected to the first signal electrode 4a, the second electrodes 52 of the MEMS pumps 5 near the second signal electrode 4b are electrically connected to the second signal electrode 4b, and so on. Since the signal electrodes 4 provide power to the neighboring MEMS pumps 5, the power transmission loss of the modulation voltage is reduced.

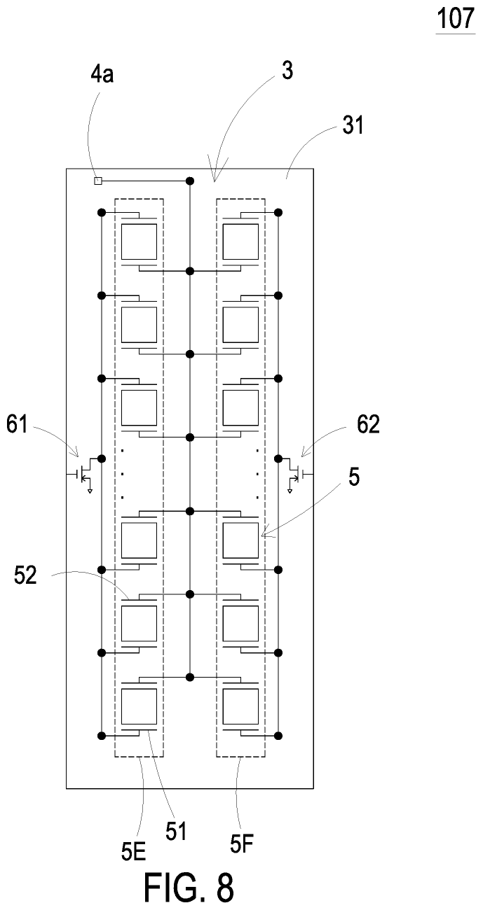

Please refer to FIG. 8. FIG. 8 schematically illustrates a MEMS chip of a MEMS pump module according to a seventh embodiment of the present disclosure. The volume of the MEMS pump 5 is so small that the transporting amount of single MEMS pump 5 is insufficient. Usually, several MEMS pumps 5 are utilized simultaneously to increase the transporting amount and improve the transporting efficient. In this embodiment, the switch unit 6 of the MEMS pump module 107 includes a first switch unit 61 and a second switch unit 62. That is, the number of the switch unit 6 is two. The first switch unit 61 and the second switch unit 62 are spatially separated from each other and are disposed on the opposite sides of the chip body 31, respectively. The plurality of MEMS pumps 5 are divided into a first MEMS actuation area 5E and a second MEMS actuation area 5F according to their positions on the chip body 31. The MEMS pumps 5 disposed adjacent to the first switch unit 61 belong to the first MEMS actuation area 5E and the first electrodes 51 of them are electrically connected to the first switch unit 61. The MEMS pumps 5 disposed adjacent to the second switch unit 62 belong to the second MEMS actuation area 5F and the first electrodes 51 of them are electrically connected to the second switch unit 62. Thereby, the MEMS pumps 5 in the first MEMS actuation area 5E and the MEMS pumps 5 in the second MEMS actuation area 5F are separately controlled by the microprocessor 7 (as shown in FIG. 2) by controlling the first switch unit 61 and the second switch unit 62, respectively. Consequently, an effect of partition and simultaneous control is achieved, and the number of pins 71 of the microprocessor 7 is reduced at the same time. In this embodiment, the microprocessor 7 includes three pins 71. Two of the pins 71 are connected to the first switch unit 61 and the second switch unit 62, respectively. The rest one of the pins 71 is connected to the first signal electrode 4a and is used to transmit the modulation voltage to the first signal electrode 4a. Consequently, the control of the MEMS pump module 107 can be achieved by only three pins 71. In conclusion, the number of the pins 71 of the microprocessor 7 is largely reduced, and the cost of the MEMS pump module 107 is reduced, concomitantly.

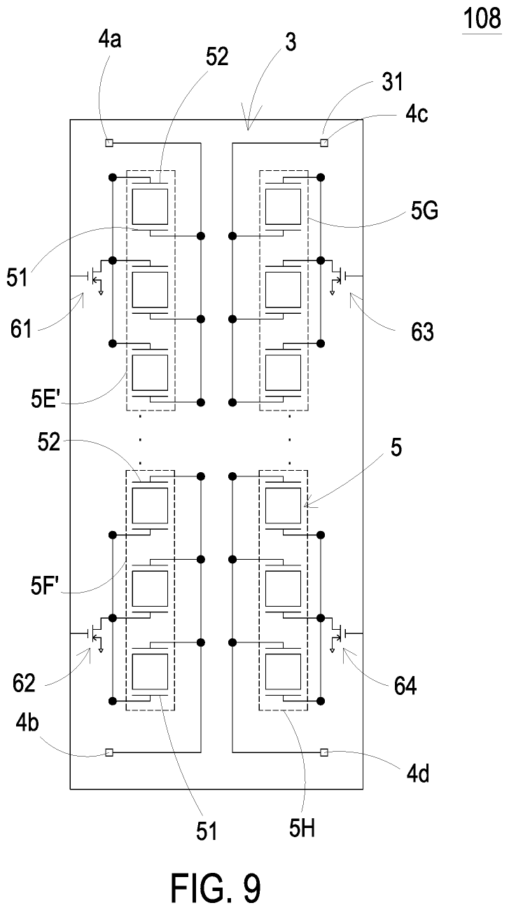

Please refer to FIG. 9. FIG. 9 schematically illustrates a MEMS chip of a MEMS pump module according to an eighth embodiment of the present disclosure. In this embodiment, the MEMS pump module 108 includes a first switch unit 61, a second switch unit 62, a third switch unit 63 and a fourth switch unit 64. That is, the number of the switch unit 6 is four. The first switch unit 61, the second switch unit 62, the third switch unit 63 and the fourth switch unit 64 are spatially separated from each other and are adjacent to the four corners of the chip body 31, respectively. The plurality of MEMS pumps 5 are divided into a first MEMS actuation area 5E′, a second MEMS actuation area 5F′, a third actuation area 5G and a fourth actuation area 5H according to their positions on the chip body 31. The MEMS pumps 5 disposed adjacent to the first switch unit 61 belong to the first MEMS actuation area 5E′ and the first electrodes 51 of them are electrically connected to the first switch unit 61. The MEMS pumps 5 disposed adjacent to the second switch unit 62 belong to the second MEMS actuation area 5F′ and the first electrodes 51 of them are electrically connected to the second switch unit 62. The MEMS pumps 5 disposed adjacent to the third switch unit 63 belong to the third MEMS actuation area 5G and the first electrodes 51 of them are electrically connected to the third switch unit 63. The MEMS pumps 5 disposed adjacent to the fourth switch unit 64 belong to the fourth MEMS actuation area 5H and the first electrodes 51 of them are electrically connected to the fourth switch unit 64. In this embodiment, the microprocessor 7 (as shown in FIG. 2) includes four pins 71. The four pins 71 of the microprocessor 7 are electrically connected to the first switch unit 61, the second switch unit 62, the third switch unit 63 and the fourth switch unit 64, respectively, thereby controlling the circuits in the first MEMS actuation area 5E′, the second MEMS actuation area 5F′, the third actuation area 5G and the fourth actuation area 5H to be opened or closed. Consequently, the first MEMS actuation area 5E′, the second MEMS actuation area 5F′, the third actuation area 5G and the fourth actuation area 5H can be separately controlled by only four pins 71. In addition, in this embodiment, the MEMS pump module 108 includes a first signal electrode 4a, a second signal electrode 4b, a third signal electrode 4c and a fourth signal electrode 4d. The first signal electrode 4a is adjacent to the first switch unit 61 and is electrically connected to the second electrodes 52 of the MEMS pumps 5 in the first MEMS actuation area 5E′. The second signal electrode 4b is adjacent to the second switch unit 62 and is electrically connected to the second electrodes 52 of the MEMS pumps 5 in the second MEMS actuation area 5F′. The third signal electrode 4c is adjacent to the third switch unit 63 and is electrically connected to the second electrodes 52 of the MEMS pumps 5 in the third MEMS actuation area 5G. The fourth signal electrode 4d is adjacent to the fourth switch unit 64 and is electrically connected to the second electrodes 52 of the MEMS pumps 5 in the fourth MEMS actuation area 5R Consequently, an effect of partition control is achieved. Meanwhile, the impedance between the signal electrodes 4 and the MEMS pumps 5 is reduced, and the power transmission loss of the modulation voltage is reduced.

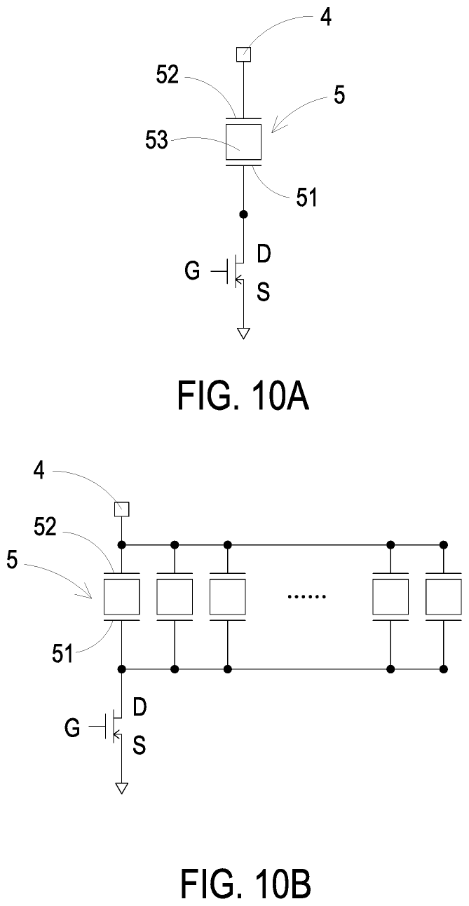

In present disclosure, the switch unit 6 of the MEMS pump module is a semiconductor switch component, such as a metal-oxide-semiconductor field-effect transistor (MOSFET). The switch units 6 can be integrated with the MEMS pumps 5 through the semiconductor process, so as to simplify the steps and reduce the cost of the wire bonding process and improve the defect-free rate. Please refer to FIGS. 10A and 10B. FIG. 10A schematically illustrates the connection between the switch unit and the MEMS pump according to of the present disclosure. FIG. 10B schematically illustrates the connection between the switch unit and the MEMS pump according to another embodiment of the present disclosure. As shown in FIG. 10A, the switch unit 6 is a MOSFET. An exemplarily embodiment utilizing a P-type metal-oxide-semiconductor field-effect transistor (PMOSFET) as the switch unit 6 is described as follow. The switch unit 6 includes a gate G a drain D and a source S. The gate G is electrically connected to the microprocessor 7 (as shown in FIG. 2). The drain D is electrically connected to the first electrode 51 of the MEMS pump 5. The source S is grounded. The control signal transmitted from the microprocessor 7 is received by the gate G of the switch unit 6, and the switch unit 6 is turned on or turned off according to the control signal. When the switch unit 6 is turned off, the circuit connected to the first electrode 51 of the MEMS pump 5 is opened. Meanwhile, the MEMS pump 5 is shut down. On the contrary, when the switch unit 6 is turned on, the first electrode 51 of the MEMS pump 5 is considered to be grounded, and a loop is formed. Under this circumstance, the MEMS pump 5 is actuated. More specifically, the modulation voltage is transmitted to and received by the second electrode 52, so that the piezoelectric element 53 is deformed, and the inner pressure within the MEMS pump 5 is adjusted to transport fluid. In present disclosure, the switch units 6 can be connected to the MEMS pumps 5 one on one. Besides, single switch unit 6 can also be connected to several MEMS pumps 5, as shown in FIG. 10B, but not limited thereto.

In addition, as the switch unit 6 is a semiconductor switch component, the switch unit 6 can be a P-type metal-oxide-semiconductor field-effect transistor (PMOSFET), a N-type metal-oxide-semiconductor field-effect transistor (NMOSFET), a complementary metal-oxide-semiconductor field-effect transistor (CMOSFET), a double-diffused metal-oxide-semiconductor field-effect transistor (DMOSFET), a lateral diffusion metal-oxide-semiconductor field-effect transistor (LDMOSFET) or combinations thereof. The semiconductor switch component can also be a bipolar junction transistor (BJT), but not limited thereto.

As described above, a MEMS pump module is provided. All of the second electrodes of the MEMS pumps are connected to the signal electrode to receive the modulation voltage transmitted from the microprocessor. There is no need to individually connect all of the second electrodes of the MEMS pump to the microprocessor. Consequently, the number of the pins of the microprocessor is largely reduced. In addition, by controlling the on-off action of the MEMS pumps through the switch unit, the microprocessor can control all of the MEMS pumps just by controlling the switch units. Consequently, the workload of the microprocessor can be reduced, the steps of packaging the MEMS pump module are simplified, and the cost of the MEMS pump module is further reduced. Furthermore, the number of the pins of the microprocessor is reduced, so that the cost of the microprocessor is also lower. If there is a need for implementing partition control, by simultaneously controlling several MEMS pumps through single switch unit, the control efficient is improved. Besides, fewer switch unit can further reduce the workload of the microprocessor and further lower the cost. In addition, since the number of components is reduced, the wire bonding process is easier to be completed, and the defect-free rate is improved.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A micro-electromechanical system (MEMS) pump module, comprising:
a MEMS chip comprising a chip body;
at least one signal electrode disposed on the chip body;
a plurality of MEMS pumps, wherein each of the plurality of MEMS pumps comprises a first electrode and a second electrode, and the second electrode is electrically connected to the at least one signal electrode; and
a plurality of switch units electrically connected to the first electrodes of the plurality of MEMS pumps,
wherein a modulation voltage is received by the at least one signal electrode and then is transmitted to the second electrodes of the plurality of MEMS pumps, and wherein the on-off actions of the plurality of MEMS pumps are controlled by the plurality of switch units.

2. The MEMS pump module according to claim 1, wherein the at least one signal electrode includes a first signal electrode.

3. The MEMS pump module according to claim 2, wherein the second electrodes of the plurality of MEMS pumps are electrically connected to the first signal electrode.

4. The MEMS pump module according to claim 2, wherein the at least one signal electrode further includes a second signal electrode.

5. The MEMS pump module according to claim 4, wherein the plurality of MEMS pumps are divided into a first MEMS pump group and a second MEMS pump group, and wherein the second electrodes of the plurality of MEMS pumps in the first MEMS pump group are electrically connected to the first signal electrode, and the second electrodes of the plurality of MEMS pumps in the second MEMS pump group are electrically connected to the second signal electrode.

6. The MEMS pump module according to claim 4, wherein the second electrodes of the plurality of MEMS pumps are electrically connected to the first signal electrode and the second signal electrode.

7. The MEMS pump module according to claim 4, wherein the at least one signal electrode further includes a third signal electrode and a fourth signal electrode.

8. The MEMS pump module according to claim 7, wherein the plurality of MEMS pumps are divided into a first MEMS pump group, a second MEMS pump group, a third MEMS pump group and a fourth MEMS pump group, and wherein the second electrodes of the MEMS pumps in the first MEMS pump group are electrically connected to the first signal electrode, the second electrodes of the MEMS pumps in the second MEMS pump group are electrically connected to the second signal electrode, the second electrodes of the MEMS pumps in the third MEMS pump group are electrically connected to the third signal electrode, and the second electrodes of the MEMS pumps in the fourth MEMS pump group are electrically connected to the fourth signal electrode.

9. The MEMS pump module according to claim 7, wherein the plurality of MEMS pumps are divided into a first MEMS pump group and a second MEMS pump group, and wherein the second electrodes of the MEMS pumps in the first MEMS pump group are electrically connected to the first signal electrode and the second signal electrode, and the second electrodes of the MEMS pumps in the second MEMS pump group are electrically connected to the third signal electrode and the fourth signal electrode.

10. The MEMS pump module according to claim 7, wherein the second electrodes of the plurality of MEMS pumps are electrically connected to the first signal electrode, the second signal electrode, the third signal electrode and the fourth signal electrode.

11. The MEMS pump module according to claim 1, wherein the plurality of MEMS pumps and the plurality of switch units are connected one on one.

12. The MEMS pump module according to claim 1, wherein the plurality of switch units include a first switch unit and a second switch unit, wherein the MEMS pumps adjacent to the first switch unit belong to a first MEMS actuation area, and the first electrodes of the MEMS pumps in the first MEMS actuation area are electrically connected to the first switch unit, and wherein the MEMS pumps adjacent to the second switch unit belong to a second MEMS actuation area, and the first electrodes of the MEMS pumps in the second MEMS actuation area are electrically connected to the second switch unit.

13. The MEMS pump module according to claim 12, wherein the plurality of switch units further include a third switch unit and a fourth switch unit, wherein the MEMS pumps adjacent to the third switch unit belong to a third MEMS actuation area, and the first electrodes of the MEMS pumps in the third MEMS actuation area are electrically connected to the third switch unit, and wherein the MEMS pumps adjacent to the fourth switch unit belong to a fourth MEMS actuation area, and the first electrodes of the MEMS pumps in the fourth MEMS actuation area are electrically connected to the fourth switch unit.

14. The MEMS pump module according to claim 13, wherein the at least one signal electrode includes a first signal electrode, a second signal electrode, a third signal electrode and a fourth signal electrode, wherein the first signal electrode is adjacent to the first switch unit and is electrically connected to the second electrodes of the plurality of MEMS pumps in the first MEMS actuation area, wherein the second signal electrode is adjacent to the second switch unit and is electrically connected to the second electrodes of the plurality of MEMS pumps in the second MEMS actuation area, wherein the third signal electrode is adjacent to the third switch unit and is electrically connected to the second electrodes of the plurality of MEMS pumps in the third MEMS actuation area, and wherein the fourth signal electrode is adjacent to the fourth switch unit and is electrically connected to the second electrodes of the plurality of MEMS pumps in the fourth MEMS actuation area.

15. The MEMS pump module according to claim 1, wherein each of the plurality of switch units is a semiconductor switch component.

16. The MEMS pump module according to claim 15, wherein the semiconductor switch component is a metal-oxide-semiconductor field-effect transistor.

17. The MEMS pump module according to claim 16, wherein the semiconductor switch units are P-type metal-oxide-semiconductor field-effect transistors, N-type metal-oxide-semiconductor field-effect transistors, complementary metal-oxide-semiconductor field-effect transistors, double-diffused metal-oxide-semiconductor field-effect transistors, lateral diffusion metal-oxide-semiconductor field-effect transistors or combinations thereof.

18. The MEMS pump module according to claim 15, wherein the semiconductor switch component is a bipolar junction transistor.

19. The MEMS pump module according to claim 1, wherein the modulation voltage is performed in a square wave, a triangle wave or a sine wave.
